(19) United States
(12) Patent Application Publication
(10) Pub. No.: US 2025/0348376 A1
(43) Pub. Date: Nov. 13, 2025

(54) MEMORY SUB-SYSTEMS WITH IMPROVED ERASURE MANAGEMENT

(71) Applicant: MICRON TECHNOLOGY, INC., Boise, ID (US)

(72) Inventor: Sai Krishna Mylavarapu, Folsom, CA (US)

(21) Appl. No.: 19/095,701

(22) Filed: Mar. 31, 2025

Related U.S. Application Data
(60) Provisional application No. 63/645,527, filed on May 10, 2024.

(51) Int. Cl. G06F 11/10

(52) U.S. Cl. CPC G06F 11/1016; G06F 11/1068

(57) ABSTRACT

A system includes a plurality of memory components; and a processing device, operatively coupled with the plurality of memory components, to perform operations including: receiving, from a host system, a request to read data stored on the plurality of memory components; determining that the data contains a plurality of errors; identifying a plurality of locations of the plurality of errors, wherein each location of plurality of locations corresponds to a respective error of the plurality of errors; responsive to determining that the plurality of locations falls in a single memory component of the plurality of memory components, excluding the single memory component from future decoding and correcting the data to generate corrected data; sending, to the host system, the corrected data; and including the single memory component for future decoding.

### RELATED APPLICATIONS

This application claims the benefit of U.S. Provisional Patent Application No. 63/645,527, filed May 10, 2024, the entire contents of which are incorporated by reference herein.

### TECHNICAL FIELD

The present disclosure generally relates to a memory sub-system, and more specifically, relates to memory sub-systems with improved erasure management.

### BACKGROUND

A memory sub-system can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various implementations of the disclosure.

FIG. 1 illustrates an example computing environment that includes a memory sub-system in accordance with some embodiments of the present disclosure.

FIG. 2 is a flow diagram of an example method to perform an error correction code decoding operation with improved erasure management in accordance with some embodiments.

FIG. 3 illustrates example data stored on memory components where the method of FIG. 2 is used to perform the error correction code decoding operation with improved erasure management in accordance with some embodiments of the present disclosure.

FIG. 4 illustrates example data stored on memory components with improved erasure management in accordance with some embodiments of the present disclosure.

FIGS. 5 and 6 are flow diagrams of example methods to perform the improved erasure management on data stored on memory components in accordance with some embodiments.

FIG. 7 is a block diagram of an example computer system in which implementations of the present disclosure may operate.

### DETAILED DESCRIPTION

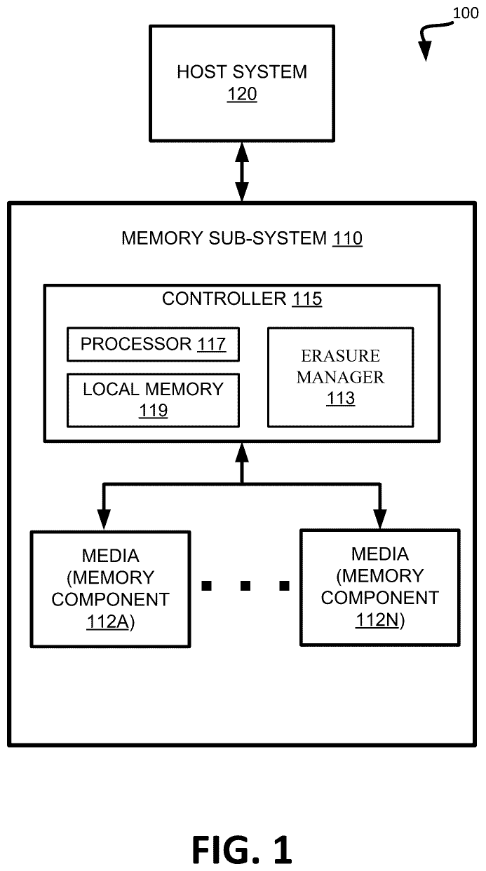

Aspects of the present disclosure are directed to a memory sub-system with improved erasure management. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1. A non-volatile memory device is a package of one or more dies. Each die includes one or more planes. For some types of non-volatile memory devices (e.g., NAND devices), each plane includes a set of physical blocks. Each block consists of a set of pages. Each page includes a set of memory cells. A memory cell is an electronic circuit that stores information. Depending on the memory cell type, a memory cell can store one or more bits of binary information, and has various logic states that correlate to the number of bits being stored. The logic states can be represented by binary values, such as “0” and “1”, or combinations of such values.

Conventionally, there are several techniques used to attempt to improve the performance and/or reduce errors included in data stored in a memory sub-system. One technique used to improve the reliability of data stored in a memory sub-system is applying error correction codes. Applying an error correction code can refer to a technique for expressing a sequence of data to enable errors introduced to the data to be detected and corrected based on the other remaining data. Typically, an encoder encodes the data to be written with additional data bits to form a codeword and stripes the codeword across the memory components of a memory sub-system. When the striped data is to be read, a decoder decodes the codeword by removing the additional data bits and providing the desired original data. The error correction code may have limitations on the number of the errors that can be detected and corrected. For example, if the number of errors exceeds a threshold number associated with the error correction code, one or more errors cannot be corrected, and in some cases, the memory component of the memory sub-system that stores the data with such errors may be identified as failed. However, in some cases, only a portion of the memory component contains the errors, while the rest of the memory component is still functional. Identifying the entire memory component as failed would exclude the entire memory component from usage and waste the memory resources that in fact still can be used.

Aspects of the present disclosure address the above and other deficiencies by providing a memory sub-system implementing an error correcting code (ECC) decoding operation with improved erasure management. Implementing the ECC decoding operation refers to applying an error correction code to data to attempt to decode the data. The error correction code decoding operation may result in decoding failure that one or more errors included in the data cannot be corrected and the locations of these errors can be identified (“erasure”). Identifying that the locations of the errors on the memory components is known can be referred to as erasure detection. In some cases, when the locations of the errors fall in one single memory component, the error correction code decoding operation may further result in identifying and marking the single memory component as failed, such that the single memory component is excluded from future decoding. The improved erasure management may enhance the erasure detection and the failure marking by unmarking the single memory component such that the single memory component is put back for future decoding, Putting back the single memory component for future decoding enables the rest memory locations in the single memory component, except for the identified locations of errors, to be used. In most cases, because the rest memory locations in the memory component are still functional, the improved erasure management may further enable identifying address(es) of the locations of errors such that the identified address(es) can directly indicate a result of the erasure detection, removing the need of performing a new erasure detection.

Specifically, a host system may send data to be stored on memory components of a memory sub-system. A controller of the memory sub-system may encode the data as a codeword and store the codeword in the memory components. A codeword can refer to the data expressed in a particular sequence to enable the detection and correction of errors introduced during transmission and storage of the data. Upon receiving a request to read the data, the controller of the memory sub-system may attempt to decode the codeword using the EEC decoding operation. The EEC decoding operation may include a first EEC decoding operation that does not use error location information and a second EEC decoding operation that uses error location information. In some implementations, the first EEC decoding operation and the second EEC decoding operation may use the same error correction codes. In some implementations, the types of error correction codes can include block codes (e.g., Reed Solomon codes, etc.).

For example, the controller of the memory sub-system may determine that one or more errors cannot be corrected using the first EEC decoding operation and thus determine that decoding using the first EEC decoding operation is unsuccessful. The controller of the memory sub-system may identify the locations of the errors and determine whether the identified location of the errors fall in a single memory component.

In some implementations, responsive to determining that the identified locations of the errors fall in a single memory component, the controller of the memory sub-system may mark the single memory component as failed and perform a second EEC decoding operation to generate corrected data. The controller of the memory sub-system may send the corrected data to the host system that requested to read the data. The controller of the memory sub-system may then unmark the single memory component to include the single memory component for future decoding. That is, when a new read request is received by the memory sub-system, the controller of the memory sub-system may still attempt to decode the data stored on the memory components including the unmarked memory component.

In some implementations, responsive to determining that the identified locations of the errors fall in a single memory component, the controller of the memory sub-system may perform a second EEC decoding operation to generate corrected data and send the corrected data to the host system that requested to read the data. In some implementations, the controller of the memory sub-system may skip the marking and unmarking operations of the single memory component, and instead, mark the address of the identified locations of the errors falling in a single memory component. In some implementations, as described above that the controller of the memory sub-system receiving a request, such request may specify the address that can be used to reference the error locations in the single memory component. The controller of the memory sub-system may mark such address, which can be used to indicate a result of an erasure detection. That is, when a new read request is received by the memory sub-system, the controller of the memory sub-system may determine whether an address specified in the new read request is marked. Responsive to determining that the address is marked, the controller of the memory sub-system may directly determine that the locations referenced by the address in the single memory component contains one or more errors without performing the regular error detection or erasure detection.

Advantages of the present disclosure include providing improved endurance of memory resources for a memory sub-system by putting a memory component that has been marked as failed back to usage. Also, the improvement of memory endurance may be achieved without adding additional memory components to the memory sub-system, thereby reducing the size and/or cost of data centers. Further, aspects of the present disclosure may avoid the latency caused by performing additional erasure detection. Aspects of the present disclosure may also improve the data reliability of a memory sub-system by reducing the probability of misidentification of failure of memory component, which can improve memory sub-system performance as a whole as access operations can succeed.

FIG. 1 illustrates an example computing environment 100 that includes a memory sub-system 110 in accordance with some embodiments of the present disclosure. The memory sub-system 110 can include media, such as memory components 112A to 112N.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory components 112A to 112N can include any combination of the different types of non-volatile memory devices and/or volatile memory devices. The volatile memory devices can be, but are not limited to, random access memory (RAM), such as dynamic random access memory (DRAM) and synchronous dynamic random access memory (SDRAM).

Some examples of non-volatile memory devices include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory components 112A to 112N can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory components 112A to 112N can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks. Some types of memory, such as 3D cross-point, can group pages across dice and channels to form management units.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory components 112A to 112N to perform operations such as reading data, writing data, or erasing data at the memory components 112A to 112N and other such operations. The controller 115 can include hardware such as one or more integrated circuits and/or discrete components, a buffer memory, or a combination thereof. The controller 115 can be a microcontroller, special purpose logic circuitry (e.g., a field programmable gate array (FPGA), an application specific integrated circuit (ASIC), etc.), or other suitable processor.

The controller 115 can include a processing device, which includes one or more processors (e.g., processor 117), configured to execute instructions stored in a local memory 119. In the illustrated example, the local memory 119 of the controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory components 112A to 112N. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical MU address, physical block address) that are associated with the memory components 112A to 112N. The memory sub-system controller 115 can further include host interface circuitry to communicate with the host system 120 via the physical host interface. The host interface circuitry can convert the commands received from the host system into command instructions to access the memory components 112A to 112N as well as convert responses associated with the memory components 112A to 112N into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory components 112A to 112N.

In some embodiments, each of the memory components 112A to 112N includes local media controllers 135 that operate in conjunction with memory sub-system controller 115 to execute operations on one or more memory cells of each of the memory components 112A to 112N. An external controller (e.g., memory sub-system controller 115) can externally manage each of the memory components 112A to 112N (e.g., perform media management operations on the memory components 112A to 112N). In some embodiments, memory sub-system 110 is a managed memory device, which is a raw memory device having control logic (e.g., local media controller 135) on the die and a controller (e.g., memory sub-system controller 115) for media management within the same memory device package. An example of a managed memory device is a managed NAND (MNAND) device.

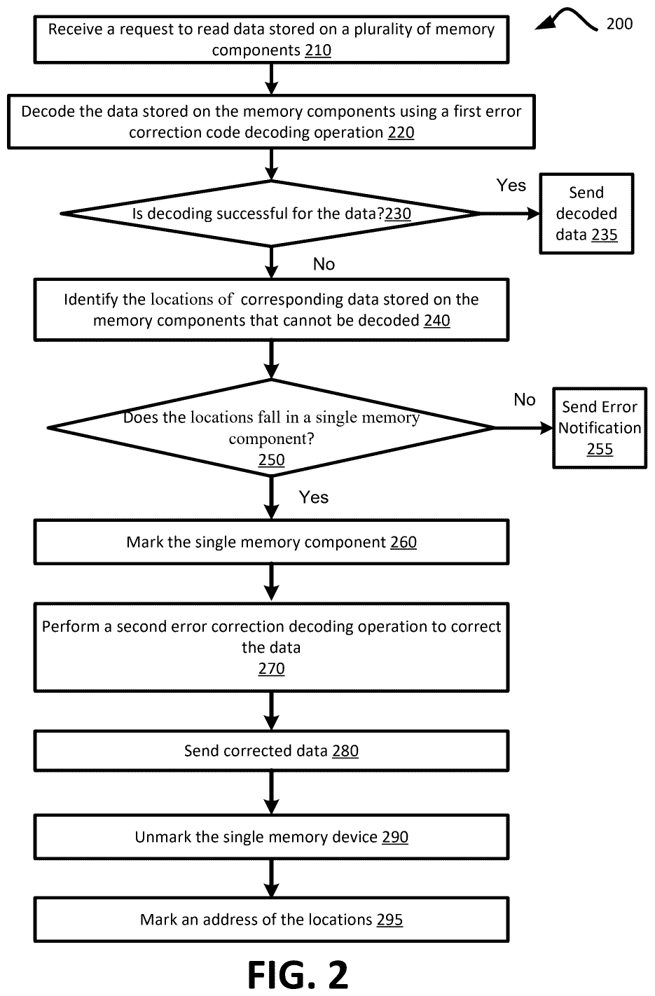

The memory sub-system 110 can include an erasure manager 113 (e.g., circuitry, dedicated logic, programmable logic, firmware, etc.) to perform the ECC decoding operation with improved erasure management. In some embodiments, the memory sub-system controller 115 includes at least a portion of the erasure manager 113. For example, the memory sub-system controller 115 can include a processor 117 (processing device) configured to execute instructions stored in local memory 119 for performing the operations described herein. In some embodiments, the erasure manager 113 is part of the host system 110, an application, or an operating system. Further details regarding the operations of the erasure manager 113 are described below with reference to FIGS. 2-6.

It will be appreciated by those skilled in the art that additional circuitry and signals can be provided, and that the components of FIG. 1 have been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

FIG. 2 is a flow diagram of an example method 200 to perform an EEC decoding operation with improved erasure management in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the erasure manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 210, the processing logic receive a request to read data stored on memory components 112A-112N. Data stored on the memory components 112A-112N includes host data that have been encoded using an ECC encoding operation. The host data refers to the original data received from a host system for storage. In some implementations, data stored on the memory components 112A-112N include codeword, and the codeword is formed by combining the host data with the redundant data (e.g., parity data) generated by the ECC encoding operation. In one example, the host system 120 may send host data to the memory sub-system 110 for storage; the controller 115 of the memory sub-system 110 may include an encoder that performs the ECC encoding operation on the host data to generate redundant data and append the redundant data to the host data to form the codeword; and the controller 115 may store the codeword in the memory components 112A-112N. In some implementations, different data blocks of the codeword can be written across respective data blocks of the memory components 112A-112N. In some implementations, each of the memory components 112A-112N is a die.

In some implementations, the ECC encoding operation operates on symbols, where each symbol represents a certain number of bits. For example, bits stored on each of memory components 112A-112N may be referred to as one respective symbol, and thus, the data (e.g., codeword) includes multiple symbols.

For example, a host system may send a request to write the original data, and an encoder in the memory sub-system may take original data as data symbols, where each data symbol refers to a fixed number of bits of the host data. The encoder may generate parity symbols and append parity symbols to data symbols, where each parity symbol refers to a fixed number of bits of the parity data. The data symbols and parity symbols together may make a codeword. The memory sub-system controller may store the codeword in one or more memory components, where the codeword comprises data symbols and parity symbols.

In some embodiments, the ECC encoding operation may use a maximum distance separable code, such as a Reed Solomon code. A Reed Solomon code encodes host data by adding extra redundant bits to the host data. A mathematical operation (e.g., polynomial) can be generated based on the host data and the redundant bits can be obtained using the mathematical operation. For example, k symbols with s bits of each symbol can be encoded into an n symbol codeword with (n-k) redundant (e.g., parity) symbols added to the k symbols. The n symbol codeword can be stored amongst the different memory components 112A-112N.

Various reasons (e.g., noisy communication, memory component failure, asynchronous power loss, etc.) can cause the data of the codeword to include errors (e.g., flipped bits, lost bits, etc.). If there are errors in the codeword stored across the memory components 112A-112N, the redundant (e.g., parity) symbols or other bits of the codeword can be used in the original mathematical operation to obtain the original host data and correct the errors in the codeword. For example, the memory sub-system can use the parity symbols to reconstruct the data symbols of one of the other memory components if that data symbols includes an error.

At operation 220, the processing device decodes the data stored on the memory components 112A-112N using a first error correction code (ECC) decoding operation. The first ECC decoding operation can include applying an ECC to the codeword to attempt to decode the codeword (e.g., removing the parity bits) and/or correct one or more errors. For example, applying the ECC to the data stored on the memory components 112A-112N may result in obtaining an updated data including at least one corrected bit, to which to change the bit including the error. In some embodiments, the first ECC decoding operation uses a Reed Solomon code, and the mathematical operation (e.g., polynomial) that was used to encode the codeword can be used with one or more original bits and/or parity bits of the codeword to obtain a corrected bit.

At operation 230, the processing device determines whether decoding is successful for the data. Decoding failure can occur when the data includes one or more errors on the memory components 112A-112N, where the error(s) cannot be corrected by the ECC decoding operation described at operation 220. That is, the processing device determines whether the data includes one or more errors that cannot be corrected by the ECC decoding operation. For example, applying the ECC to the data stored on the memory components 112A-112N may result in decoding failure because the number of errors exceeds the maximum number of the errors can be corrected by applying the ECC. The maximum number of the errors may be a number of the corresponding data on the memory components 112A-112N that cannot be reconstructed by a ECC decoding operation.

In some embodiments, the first ECC decoding operation uses a Reed Solomon code, and the maximum number of errors that can be corrected is m symbols (e.g., 3 symbols for Reed Solomon code (72, 64, 8)). When the data includes the errors on m symbols or less than m symbols, the processing device determines that decoding is successful for the data. When the data includes the errors on more than m symbols, the processing device determines that decoding is not successful for the data.

If decoding is successful for the data, the processing device provides the decoded data at operation 235. The decoded data can be provided to a requester (e.g., the host system 120) that requested to access the data. If decoding is not successful for data, then at operation 240, the processing device identifies the locations of the error occurrence. For example, the processing device identifies the plurality of locations of the plurality of errors, wherein each location of plurality of locations corresponds to a respective error of the plurality of errors. That is, at operation 240, the processing device identifies the location of corresponding data stored on the memory components 112A-112N that cannot be decoded by decoding at operation 220.

In some embodiments, at operation 240, the processing device may identify the location by performing a mathematical operation and evaluating the polynomial at certain locations, typically corresponding to the roots of the primitive polynomial used in encoding. The error location polynomial is constructed based on a set of equations using methods such as the Berlekamp-Massey algorithm.

At operation 250, the processing device determines whether the locations identified at operation 240 falls in a single memory component. That is, the processing device determines whether locations of the error occurrence fall in a single memory component. For example, the processing device may assume that locations of the error occurrence fall in a single memory component, attempt to recover these errors, and obtain a fail-to-recover response to identify that the locations of the error occurrence fall in a single memory component.

At operation 255, responsive to determining that the locations falls in a single memory component, the processing device determines the errors cannot be corrected and send an error notification regarding the request to read data.

At operation 260, responsive to determining that the locations fall in a single memory component, the processing device marks the single memory component as failed (e.g., temporary erasure). Marking the single memory component may result in excluding the single memory component from future memory allocation, avoiding future decoding data stored on the single memory component, and/or sending an error message in response to receiving a request to access the single memory component.

At operation 260, the processing device performs a second EEC decoding operation to correct the data to generate the corrected data, and at operation 270, sends the corrected data to a requester (e.g., the host system 120) that requested to access the data. In some embodiments, because the processing device knows the locations of the errors and marks the single memory component as failed, the processing device may perform a second EEC operation (e.g., a redundancy operation) to correct the data. The redundancy operation may include a logical operation, using information of the locations of the errors, performed on the data to reconstruct the data. The redundancy operation can include identifying data stored in the memory components that can be decoded and applying a logical operation (e.g., exclusive-or (XOR)) based on the identified data to reconstruct the corresponding data on the memory components that could not be decoded. For example, the data symbols stored in one of the memory components 112A-112N includes an error, the processing device may perform a redundancy operation on the error-free data symbols of the other memory components to reconstruct the data symbols with the error. The redundancy operations may guarantee that the errors in the data symbols are removed by reconstructing the data symbols for the memory component including the data symbols with the error.

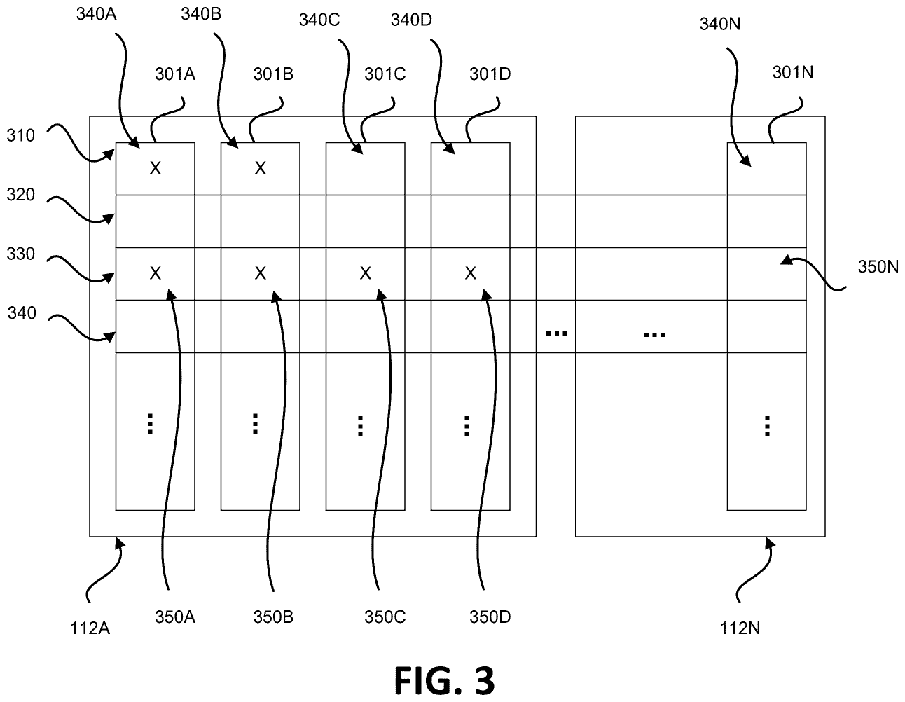

Using FIG. 3 as an illustrative example of the memory components 112A-112N, FIG. 3 illustrates example data symbols 301A, 301B, 301C, 301D stored on the memory component 112A. Each data symbol 301A-301D may include strips of data 310, 320, 330, 340, and more. Striping refers to splitting data into data blocks that are written across each memory component of the memory components 112A-112N. In some implementations, each data strip 310-340 may represent a codeword that was encoded prior to being written to the memory components 112A-112N. Accordingly, each data strip 310-340 can include original data that is to be stored and additional parity data that is determined using the error correction code and added to the original data. Each data strip 310-340 can include any suitable amount of data. In some implementations, the data strip 310-340 can be read in any order as determined by the host system 120 or upon request by a user of the host system 120. In some implementations, each data strip 310-340 may correspond to an address or a range of addresses referencing a location (e.g., bit 1, bit 2, etc.) of the memory components 112A-112N.

As illustrated in FIG. 3, the processing device may receive a request to read the data strip 310 (e.g., operation 210). In some implementations, the request specifies an address or an address range that corresponds to the data strip 310. The processing device may decode each data block 340A-340N of the data strip 310 stored on the memory components 112A-112N (e.g., operation 220). Decoding of the data strip 310 can be attempted, but as illustrated, data blocks 340A and 340B of the data strip 310 may include data with one or more errors (represented by X's). The processing device may perform an error correction code decoding operation (e.g., the first EEC decoding operation) (e.g., operation 230) to remove the errors of the data blocks 340A and 340B. Once the errors of data blocks 340A and 340B are removed, the data strip 310 can be decoded, and the processing device may determine that the decoding is successful. The processing device may send the decoded data strip 310 to the requester (e.g., the host system 120) that requested to read the data strip 310.

As further illustrated in FIG. 3, the processing device may receive a request to read the data strip 330 (e.g., operation 210). In some implementations, the request specifies an address or an address range that corresponds to the data strip 330. The processing device may decode each data block 350A-350N of the data strip 330 stored on the memory components 112A-112N (e.g., operation 220). Decoding of the data strip 330 can be attempted, but as illustrated, data blocks 350A, 350B, 350C, and 350D of the data strip 330 may include data with one or more errors (represented by X's). The processing device may perform an error correction code decoding operation (e.g., the first EEC decoding operation) (e.g., operation 230) but fails to remove the errors of the data blocks 350A-350D. For example, the error correction code decoding operation may be limited to remove three of the errors of the data blocks 350A-350D, and the processing device may determine that one or more errors of the data blocks 350A-350D cannot be corrected and thus determine the decoding is not successful. The processing device may identify the locations of the errors of the data blocks 350A-350D (e.g., operation 250). The processing device may determine that the locations of the errors of the data blocks 350A-350D fall in the memory component 112A (e.g., operation 250). In the case that the locations of the errors of the data blocks (not shown) do not fall in the memory component 112A, the processing device may send, to a requester (e.g., the host system 120) that requested to read the data, a notification indicating an error regarding the request.

Once the processing device determines that the locations of the errors of the data blocks 350A-350D fall in the memory component 112A, the processing device may mark the data blocks 350A-350D as erasure, which means that each of the data blocks 350A-350D contains an error (or erased data), and mark the memory component 112A (e.g., operation 260) as failed, which means that the memory component 112A is excluded form future decoding.

In some embodiments, the processing device may perform another error correction code decoding operation (e.g., the second EEC decoding operation) (e.g., operation 270) to generate corrected data strip 330. The processing device may send the corrected data strip 330 to the requester (e.g., the host system 120) that requested to read the data strip 330.

Referring back to FIG. 2, subsequent to performing one or more error correction decoding operations as described above (e.g., operations 220-280), the memory component 112A (e.g., operation 260) is marked as failed, which means that the memory component 112A is excluded form future decoding. At operation 290, the processing device may unmark the single memory component (e.g., memory component 112A of FIG. 3). Unmarking the single memory component may result in including the single memory component for future memory allocation, and/or enabling data stored on the single memory component for future decoding.

As shown in FIG. 3, the data blocks of the memory component 112A that does not contain an error exist in a great amount, such as the data blocks of data strips 320 and 340, unmaking the memory component 112A may put these data blocks back in use of decoding. In some implementations, unmarking the memory component means that the memory component 112A is included for future decoding.

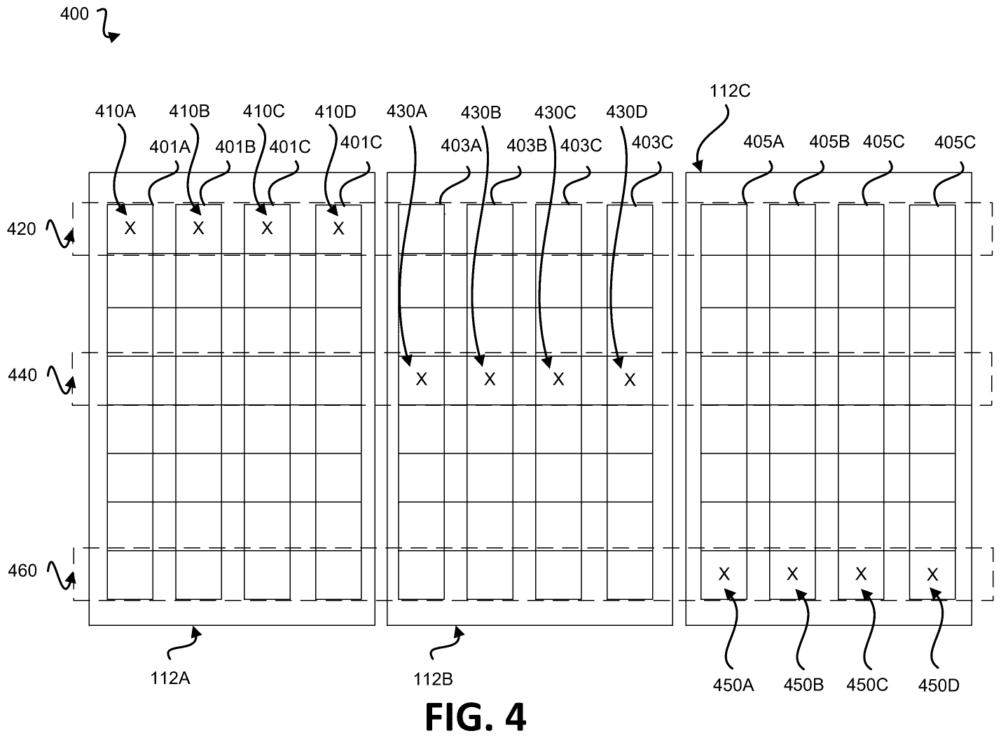

In some implementations, at operation 295, the processing device may mark an address or a range of addresses of the locations identified at operation 240. Marking the address(es) may put a notice that data stored in the address(es) that corresponds to the marked-and-unmarked memory component contains one or more errors, and as such, the address(es) can be used to avoid future error correction operations directed to the address(es), such as avoid operations 220, 230, 240, 250, and/or 270. For example, as shown in FIG. 4, data symbols 401A, 401B, 401C, 401D are stored on the memory component 112A, data symbols 403A, 403B, 403C, 403D are stored on the memory component 112B, and data symbols 405A, 405B, 405C, 405D are stored on the memory component 112C.

Each of data block 410A of data symbols 401A, data block 410B of data symbols 401B, data block 410C of data symbols 401C, and data block 410D of data symbols 401D contains one or more errors (represented by X's). The data blocks 410A-410D correspond to an address of the location 420. The processing device may mark the address of the location 420 of the memory component 112A. In some implementations, the processing device may receive an access request including the address of the location 420, and may determine whether the address of the location 420 is marked. Responsive to determining that the address of the location 420 is marked, the processing device may avoid performing the error detection and/or erasure detection.

Each of data block 430A of data symbols 403A, data block 430B of data symbols 403B, data block 430C of data symbols 403C, and data block 430D of data symbols 403D contains one or more errors (represented by X's). The data blocks 430A-430D correspond to an address of the location 440. The processing device may mark the address of the location 440 of the memory component 112B. In some implementations, the processing device may receive an access request including the address of the location 440, and may determine whether the address of the location 440 is marked. Responsive to determining that the address of the location 440 is marked, the processing device may avoid performing the error detection and/or erasure detection.

Each of data block 450A of data symbols 405A, data block 450B of data symbols 405B, data block 450C of data symbols 405C, and data block 450D of data symbols 405D contains one or more errors (represented by X's). The data blocks 450A-450D correspond to an address of the location 460. The processing device may mark the address of the location 460 of the memory component 112C. In some implementations, the processing device may receive an access request including the address of the location 460, and may determine whether the address of the location 460 is marked. Responsive to determining that the address of the location 460 is marked, the processing device may avoid performing the error detection and/or erasure detection.

As shown in FIG. 4, the processing device may mark the addresses of multiple locations (e.g., the location 420 of the memory component 112A, the location 440 of the memory component 112B, and the location 460 of the memory component 112C).

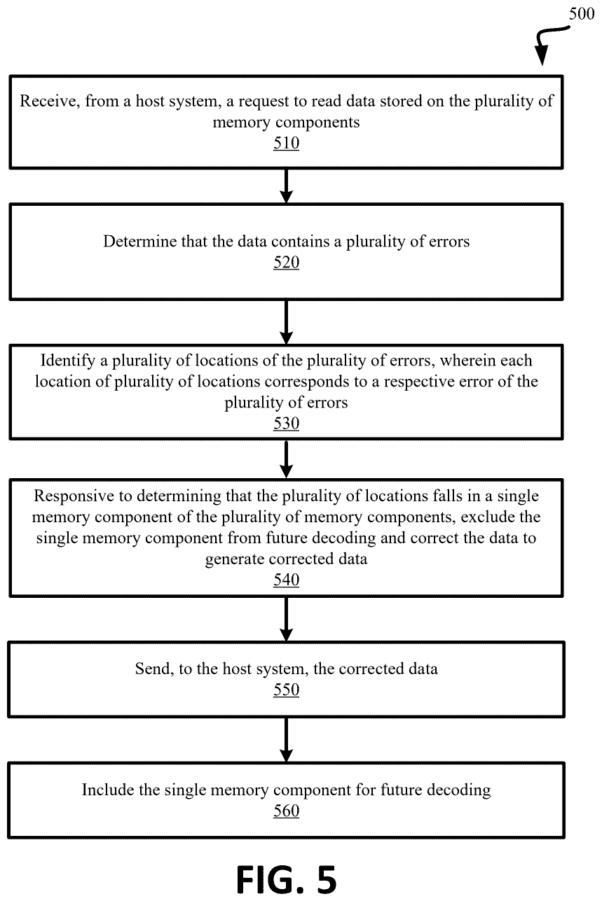

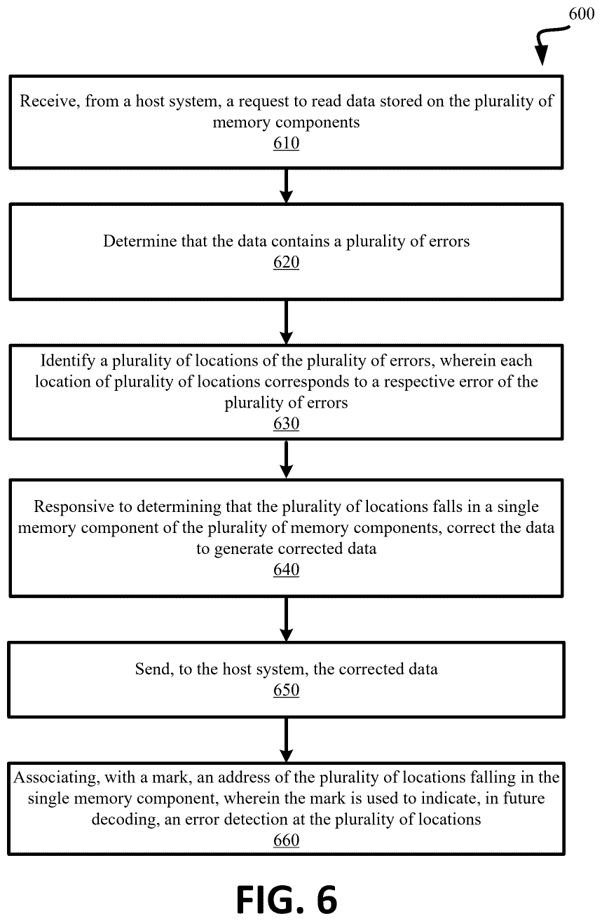

FIGS. 5 and 6 are flow diagrams of example methods 500 and 600 to perform an error correction code decoding operation with improved erasure management on data stored on memory components 112A-112N in accordance with some embodiments. The methods 500 and 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the methods 500 and 600 are performed by the erasure manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing device may receive, from a host system (e.g., host system 120), a request to read data stored on the memory components 112A-112N. The data may include a strip of data that represents a codeword encoded using an error correction code. In some implementations, the error correction code comprises Reed Solomon code. In some implementations, the operation 510 may be the same as or similar to the operation 210.

At operation 520, the processing device may determine that the data contains a plurality of errors. In some embodiments, the processing device can decode the codeword using the error correction code (e.g., first ECC decoding operation) and determine that the plurality of errors cannot be corrected by the first ECC decoding operation. In some instances, the data can include one or more errors that prevent corresponding data from being decoded successfully. In some implementations, applying the error correction code to the data stored on memory components 112A-112N obtains an updated data including at least one corrected bit. In some implementations, applying the error correction code can include applying a mathematical operation to a portion or all of the data to derive the corrected bit. The corrected bit can be used to change the bit with the error. In some implementations, the processing device may determine that a number of errors exceeds a maximum number of errors that can be corrected by the first ECC decoding operation. In some implementations, the processing device may determine that a number of data blocks with one or more errors exceeds a maximum number of data that can be corrected by the first ECC decoding operation. In some implementations, the processing device may determine that a number of symbols with one or more errors exceeds a maximum number of symbols that can be corrected by the first ECC decoding operation. In some implementations, the operation 520 may be the same as or similar to the operations 220 and 230.

At operation 530, the processing device may identify a plurality of locations of the plurality of errors, wherein each location of plurality of locations corresponds to a respective error of the plurality of errors. In some implementations, the operation 530 may be the same as or similar to the operation 240.

At operation 540, responsive to determining that the plurality of locations falls in a single memory component of the plurality of memory components, the processing device may exclude the single memory component from future decoding and correct the data to generate corrected data. In some implementations, correcting the data to generate the corrected data is performed using an error correction code (ECC) decoding operation (e.g., a second ECC decoding operation). The processing device performs a redundancy operation on the data blocks to correct a particular data block of the data blocks that includes an error, where the redundancy operation can include using parity data with the data stored on memory components 112A-112N to obtain an updated data including at least one corrected bit. In some implementation, to perform the redundancy operation, the processing device can identify a subset of data blocks of memory components 112A-112N that do not include errors and apply a logical operation (e.g., XOR) based on the subset of data blocks to reconstruct the data of the other data blocks that include an error. As depicted, after performing the EEC decoding operation, the data is corrected and the error is removed at operation 540. In some implementations, the operation 540 may be the same as or similar to the operations 250, 260, and 270.

At operation 550, the processing device may send, to the host system, the corrected data. That is, the error-free data can be read and provided to a requester (e.g., host system 120). In some implementations, the operation 550 may be the same as or similar to the operation 280.

At operation 560, the processing device may include the single memory component for future decoding. The single memory component that is excluded from future decoding at operation 540 is now put back for future decoding. In some implementations, the operation 560 may be the same as or similar to the operation 290.

Referring to FIG. 6, at operation 610, the processing device may receive, from a host system (e.g., host system 120), a request to read data stored on the memory components 112A-112N. The data may include a strip of data that represents a codeword encoded using an error correction code. In some implementations, the error correction code comprises Reed Solomon code. In some implementations, the operation 610 may be the same as or similar to the operation 210.

At operation 620, the processing device may determine that the data contains a plurality of errors. In some embodiments, the processing device can decode the codeword using the error correction code (e.g., first ECC decoding operation) and determine that the plurality of errors cannot be corrected by the first ECC decoding operation. In some instances, the data can include one or more errors that prevent corresponding data from being decoded successfully. In some implementations, applying the error correction code to the data stored on memory components 112A-112N obtains an updated data including at least one corrected bit. In some implementations, applying the error correction code can include applying a mathematical operation to a portion or all of the data to derive the corrected bit. The corrected bit can be used to change the bit with the error. In some implementations, the processing device may determine that a number of errors exceeds a maximum number of errors that can be corrected by the first ECC decoding operation. In some implementations, the processing device may determine that a number of data blocks with one or more errors exceeds a maximum number of data that can be corrected by the first ECC decoding operation. In some implementations, the processing device may determine that a number of symbols with one or more errors exceeds a maximum number of symbols that can be corrected by the first ECC decoding operation. In some implementations, the operation 620 may be the same as or similar to the operations 220 and 230.

At operation 630, the processing device may identify a plurality of locations of the plurality of errors, wherein each location of plurality of locations corresponds to a respective error of the plurality of errors. In some implementations, the operation 630 may be the same as or similar to the operation 240.

At operation 640, responsive to determining that the plurality of locations are associated with a single memory component of the plurality of memory components, the processing device may correct the data to generate corrected data. In some implementations, correcting the data to generate the corrected data is performed using an error correction code (ECC) decoding operation (e.g., a second ECC decoding operation). The processing device performs a redundancy operation on the data blocks to correct a particular data block of the data blocks that includes an error, where the redundancy operation can include using parity data with the data stored on memory components 112A-112N to obtain an updated data including at least one corrected bit. In some implementation, to perform the redundancy operation, the processing device can identify a subset of data blocks of memory components 112A-112N that do not include errors and apply a logical operation (e.g., XOR) based on the subset of data blocks to reconstruct the data of the other data blocks that include an error. As depicted, after performing the EEC decoding operation, the data is corrected and the error is removed at operation 640. In some implementations, the operation 640 may be the same as or similar to the operations 250 and 270. In some implementations, the processing device may avoid excluding the single memory component from future decoding. In some implementations, the processing device may avoid marking the single memory component as failed.

At operation 650, the processing device may send, to the host system, the corrected data. That is, the error-free data can be read and provided to a requester (e.g., host system 120). In some implementations, the operation 650 may be the same as or similar to the operation 280.

At operation 660, the processing device may mark one or more addresses (e.g., an address or a range of addresses) of the plurality of locations associated with the single memory component, wherein the marking is to indicate, in future decoding, an error detection and/or erasure detection at the plurality of locations, instead of performing traditionally-used error correction operation(s). That is, the marked address is used to indicate that data stored in the address(es) contains one or more errors, and as such, the address(es) can be used to avoid future error correction operations directed to the address(es). In some implementations, the operation 560 may be the same as or similar to the operation 295.

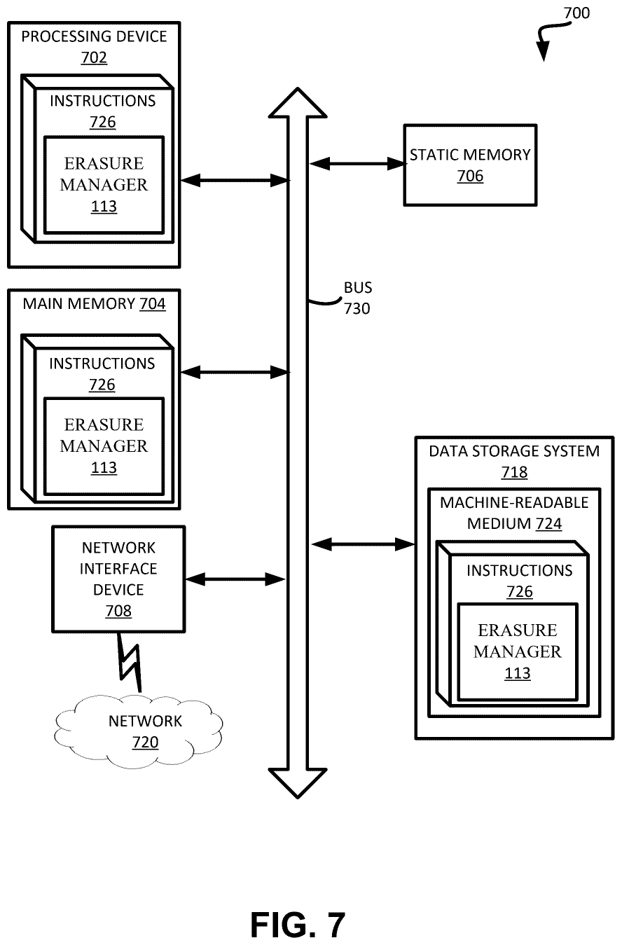

FIG. 7 illustrates an example machine of a computer system 700 within which a set of instructions, for causing the machine to perform any one or more of the methodologies discussed herein, can be executed. In some embodiments, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the erasure manager 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the operations and steps discussed herein. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1.

In one embodiment, the instructions 726 include instructions to implement functionality corresponding to a managing component (e.g., the erasure manager 113 of FIG. 1). While the machine-readable storage medium 724 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a plurality of memory components; and
a processing device, operatively coupled with the plurality of memory components, to perform operations comprising:
receiving, from a host system, a request to read data stored on the plurality of memory components;
determining that the data contains a plurality of errors;
identifying a plurality of locations of the plurality of errors, wherein each location of plurality of locations corresponds to a respective error of the plurality of errors;
responsive to determining that the plurality of locations falls in a single memory component of the plurality of memory components, excluding the single memory component from future decoding and correcting the data to generate corrected data;
sending, to the host system, the corrected data; and
including the single memory component for future decoding.

2. The system of claim 1, the operations further comprise:
marking an address of the plurality of locations of the single memory component;
responsive to receiving a second request specifying the address, determining whether the address is marked; and
responsive to determining that the address is marked, determining that a set of locations corresponding to the address is known to contain one or more errors.

3. The system of claim 2, wherein the request specifies the address.

4. The system of claim 1, wherein determining that the data contains the plurality of errors further comprises:
decoding the data using an error correction code (ECC) decoding operation; and
determining that the plurality of errors cannot be corrected by the error correction code (ECC) decoding operation.

5. The system of claim 4, wherein determining that the plurality of errors cannot be corrected by the error correction code (ECC) decoding operation further comprises:
determining whether a number of the plurality of errors exceeds a maximum number of errors that can be corrected by the error correction code (ECC) decoding operation.

6. The system of claim 1, wherein correcting the data to generate the corrected data is performed using an error correction code (ECC) decoding operation.

7. The system of claim 1, wherein the data comprises a plurality of symbols, and wherein each of the plurality of symbols contains a respective error of the plurality of errors.

8. The system of claim 1, wherein each of the plurality of memory components is a die.

9. A method comprising:
receiving, by a processing device, from a host system, a request to read data stored on a plurality of memory components;
determining that the data contains a plurality of errors;
identifying a plurality of locations of the plurality of errors, wherein each location of plurality of locations corresponds to a respective error of the plurality of errors;
responsive to determining that the plurality of locations are associated with a single memory component of the plurality of memory components, correcting the data to generate corrected data;
sending the corrected data to the host system; and
marking an address of the plurality of locations associated with the single memory component, wherein the marking is to indicate, in future decoding, that an error was detected at the plurality of locations.

10. The method of claim 9, further comprising:
responsive to receiving a second request specifying the address, determining whether the address is marked; and
responsive to determining that the address is marked, determining that a set of locations corresponding to the address is known to contain one or more errors.

11. The method of claim 9, wherein the request specifies the address.

12. The method of claim 9, wherein determining that the data contains the plurality of errors further comprises:
decoding the data using an error correction code (ECC) decoding operation; and
determining that the plurality of errors cannot be corrected by the error correction code (ECC) decoding operation.

13. The method of claim 12, wherein determining that the plurality of errors cannot be corrected by the error correction code (ECC) decoding operation further comprises:
determining whether a number of the plurality of errors exceeds a maximum number of errors that can be corrected by the error correction code (ECC) decoding operation.

14. The method of claim 9, wherein correcting the data to generate the corrected data is performed using an error correction code (ECC) decoding operation.

15. The method of claim 9, wherein the data comprises a plurality of symbols, and wherein each of the plurality of symbols contains a respective error of the plurality of errors.

16. The method of claim 9, wherein each of the plurality of memory components is a die.

17. A non-transitory computer-readable storage medium comprising instructions that, when executed by a processing device, cause the processing device to perform operations comprising:
receiving, from a host system, a request to read data stored on a plurality of memory components;
determining that the data contains a plurality of errors;
identifying a plurality of locations of the plurality of errors, wherein each location of plurality of locations corresponds to a respective error of the plurality of errors;
responsive to determining that the plurality of locations falls in a single memory component of the plurality of memory components, excluding the single memory component from future decoding and correcting the data to generate corrected data;
sending, to the host system, the corrected data; and
including the single memory component for future decoding.

18. The non-transitory computer-readable storage medium of claim 17, the operations further comprise:
marking an address of the plurality of locations of the single memory component;
responsive to receiving a second request specifying the address, determining whether the address is marked; and
responsive to determining that the address is marked, determining that a set of locations corresponding to the address is known to contain one or more errors.

19. The non-transitory computer-readable storage medium of claim 18, wherein the request specifies the address.

20. The non-transitory computer-readable storage medium of claim 17, wherein determining that the data contains the plurality of errors further comprises:
decoding the data using an error correction code (ECC) decoding operation; and
determining that the plurality of errors cannot be corrected by the error correction code (ECC) decoding operation.
